(19) United States
(12) Patent Application Publication
(10) Pub. No.: US 2006/0097241 A1
(43) Pub. Date: May 11, 2006

(54) Novel class of superlattice materials and superlattice precursors, and method for their manufacture and use

(76) Inventors: Fred Raymel Harris, Covina, CA (US); David Charles Johnson, Eugene, OR (US)

Correspondence Address: KLARQUIST SPARKMAN, LLP, 121 SW SALMON STREET, SUITE 1600, PORTLAND, OR, 97204, US

(21) Appl. No.: 10/522,346

(22) PCT Filed: Jul. 28, 2003
(86) PCT No.: PCT/US03/23606

§ 371 Date: Sep. 26, 2005

Related U.S. Application Data
(60) Provisional application No. 60/398,953, filed on Jul. 26, 2002.

(51) Int. Cl. H01L 29/06

(52) U.S. Cl. 257/9

(57) ABSTRACT

The present disclosure concerns novel materials comprising at least two crystalline materials. In certain embodiments, at least one of the crystalline materials is a diffusion barrier, and at least one material has a high power factor. The disclosed materials are particularly useful as superlattices, particularly thermoelectric superlattices, and superlattice precursors. A method for synthesizing such superlattices is provided. An embodiment of the method includes using Modulated Elemental Reactants (MER) to deposit layers of superlattice precursor materials, followed by annealing to yield bulk superlattice materials.

### CROSS REFERENCE TO RELATED APPLICATION

This application claims the benefit of the earlier filing date of U.S. provisional application No. 60/398,953, filed Jul. 26, 2002, which is incorporated herein by reference.

### ACKNOWLEDGEMENT OF GOVERNMENT SUPPORT

This invention was made in part using funds provided by National Sciences Foundation Grant Nos. DMR 9813726, DMR 0103409, and DGE 0114419. The United States government may have certain rights in this invention.

### FIELD

This application concerns a novel composition of matter, particularly a superlattice composition, even more particularly a thermoelectric superlattice composition, comprising two crystalline materials, at least one of which functions as a diffusion barrier, and embodiments of a method for their manufacture and use.

### BACKGROUND

Thermoelectric materials can directly convert thermal energy into electricity, and conversely, can convert electricity into thermal energy. Thermoelectric materials can be used for many different applications, which typically fall into two general categories: power generation and cooling devices. Researchers have proposed using thermoelectric materials for such diverse applications as converting waste heat energy into electrical power in automobiles and internally spot-cooling microelectronic components. Voss, D. Technology Review, April 2002, 29. Unfortunately, known thermoelectric materials currently have limited utility in devices because of their efficiency.

Two effects are known to govern thermoelectric behavior: the Peltier effect and the Seebeck effect. The Seebeck effect is demonstrated when two conducting materials are joined at two different places, and each junction is kept at a different temperature. A potential difference forms between the two materials and current flows between them, as illustrated in FIG. 1, where the arrows indicate current flow.

The Peltier effect is the converse of the Seebeck effect. If a current is forced to flow through two materials that are connected at two constant temperature junctions, the junctions will absorb or release heat as current flows from one material to another (see FIG. 2). CRC Handbook of Thermoelectric; Rowe, D. M., Ed.; CRC Press: New York, 1995.

The energy transfer efficiency of such devices is related to the figure of merit. For a pair of materials, the figure of merit is defined by Formula 1:

$$Z = {[ \frac{{S}_{1} - {S}_{2}}{{( {ρ}_{1} {κ}_{1} )}^{\frac{1}{2}} + {( {ρ}_{2} {κ}_{2} )}^{\frac{1}{2}}} ]}^{2} \qquad Formula 1$$

where Z is the figure of merit, S is the Seebeck coefficient, K is the thermal conductivity, and ρ is the resistivity. The figure of merit for a single material is given by Formula 2:

$$ZT = ( \frac{σ {S}^{2}}{κ} ) T \qquad Formula 2$$

where Z is defined as the figure of merit of a thermoelectric material, a is the electrical conductivity, S is the Seebeck coefficient, T is the temperature in Kelvin, and κ is the total thermal conductivity, including both electronic and lattice contributions.

In Formula 2, the figure of merit (Z) is maximized when the electrical properties of the material are maximized and the thermal conductivity of the material is minimized. Most metals have small Seebeck- coefficients and high electrical conductivities, but also have large thermal conductivities. Most insulators have high Seebeck coefficients and low thermal conductivities, but very low electrical conductivities.

Good thermoelectric materials ideally have properties from both types of materials. These materials typically have a high power factor value, ο•S²T, which is calculated from the numerator of the unitless figure of merit equation in Formula 2. Materials Research Society: Symposium Proceedings, Vol. 691 Thermoelectric Materials 2001 —Research and Applications. Editors: George S. Nolas, David C. Johnson, David G. Mandrus, Materials Research Society, 2002 Overview of Various Strategies and Promising New Bulk Materials for Potential Thermoelectric Applications; pp. 3-14.

With reference to Formula 2, where thermal conductivity (κ) is reduced, the figure of merit is increased. A method for reducing the thermal conductivity of materials that is exploited herein involves using superlattices to reduce thermal conductivity and therefore increase the figure of merit.

Superlattice materials are of interest as thermoelectric materials. Bi₂Te₃/Sb₂Te₃ superlattices have been synthesized in thin film form and the thermoelectric properties of these thin films were evaluated. Venkatasubramanian, R.; Colpitts, T. In Thermoelectric Materials—New Directions and Approaches; Tritt, T. M., Kanatzidis, M. G., Hylan B. Lyon, J., Mahan, G. D., Eds.; Materials Research Society: San Francisco, Calif., 1997; Vol. 478, pp. 73-84, which is incorporated herein by reference. These films were prepared using epitaxial metallorganic chemical vapor deposition (MOCVD). Superlattices with a repeat distance (i.e., the thickness of the superlattice repeat unit), of 10 to 100 Å were found to have a three-to four-factor reduction in thermal conductivity compared to the corresponding bulk alloy. From this, the unitless figure of merit (ZT) was calculated to be approximately 2 at 300K. This is significantly higher than ZT≈1 for the p-type Bi_{0.5}Sb_{1.5}Te₃ alloy and ZT≈0.9 for the n-type Bi₂Te_{2.85}Se_{0.15} alloys, which are commonly used in thermoelectric devices. These results indicated a maximum efficiency was achieved at a superlattice repeat thickness of approximately 50 to 70 Å. Venkatasubramanian, R.; Colpitts, T.; Watko, E.; Lamvik, M. Journal of Crystal Growth 1997, 170, 817-821.

Epitaxial MOCVD is not suitable for making bulk superlattices. Since thermoelectric devices require bulk material, methods for producing such bulk materials are needed. Moreover, the properties of superlattice materials should be determined on the bulk materials to ensure that the thermoelectric properties are retained in bulk samples.

### SUMMARY

The present disclosure concerns a novel class of material, particularly thermoelectric superlattices, and a method for synthesizing such superlattices. The superlattices are comprised of layers of thermoelectric materials. The present superlattices typically include at least two different materials, and can include three or more different materials operatively positioned relative to one another to define a superlattice, such as by being stacked on one another. The superlattice typically is formed on a substrate, such as silicon, silicon nitride, glass, plastics, insulating oxides, semiconductor materials, quartz, mica, metals, and combinations thereof. The different materials of the superlattice each form a substantially discrete superlattice component layer.

Generally, the superlattice includes a first material, typically having a high power factor, and a second material that functions as a diffusion barrier. Each layer can include elements, such as antimony, bismuth, hafnium, lead, selenium, tellurium, titanium, zirconium and combinations thereof. Particular embodiments of superlattice layers can comprise any material, or combinations of materials, which are described as metal chalcogenides. Typical examples of metal chalcogenides include those having the general formula Bi,Sb₂₋ₓSe_{y}Te_{3-y}, or PbSe_{z}Te_{1-z}, where 0≦x≦2, 0≦y≦3, and 0≦z≦1. Certain superlattice layers will include materials fitting one formula or both formulas. For example a superlattice layer can include a first material such as one satisfying a formula provided above, for example Bi₂Te₃, or such a material alloyed with a second material, e.g. a material having a formula provided above, e.g. PbSe_{z}Te_{1-z} where 0≦z≦1. Similarly, certain superlattices will include different materials fitting one formula, or both formulas. Superlattices can, for example, include a material selected from the group consisting of Bi₂Te₃, Sb₂Te₃, Bi₂Se₃, Sb₂Se₃, PbSe, PbTe, alloys thereof, and combinations thereof. For example, without limitation, a superlattice can include both Bi₂Te₃ and Sb₂Te₃, and a superlattice can include both Bi₂Te₃ and PbTe.

The superlattice typically includes at least one layer that functions as a diffusion barrier. The diffusion barrier layer serves to maintain the integrity of the superlattice layers, such that they remain substantially discrete and layer interdiffusion is minimized. The diffusion barrier layer can comprise any material or combinations of materials capable of functioning as a barrier material. Particular embodiments used barriers having the formula ASe_{z}Te_{2-z}, where A includes, without limitation, Ti, Zr, Hf, V, Nb, Ta, Cr, Mo, W, and combinations thereof, and 0≦z≦2. By way of example and without limitation, diffusion barrier materials according to the formula ASe_{z}Te_{2-z}, include TiTe₂, HfTe₂, ZrTe₂, TiSe₂, HfSe₂, ZrSe₂, VSe₂, NbSe₂, TaSe₂, CrSe₂, MoSe₂, MoSe₂, WSe₂, VTe₂, NbTe₂, TaTe₂, CrTe₂, MoTe₂, WTe₂, alloys thereof, and combinations thereof. Mixed anion diffusion barrier materials also can be used, such as TiSeTe and HfSeTe. These materials are referred to as mixed anion materials because they each have two different chalcogens. A particular example diffusion layer useful for forming superlattices including Bi₂Te₃, Sb₂Te₃, or both, is TiTe₂. Exemplary superlattices can be represented as a whole by the repeating unit [(Bi₂Te₃)ₓ(TiTe₂)_{y})], where x and y refer to the number of contiguous repeat layers for Bi₂Te₃ and TiTe₂, respectively.

A method for synthesizing individual superlattice component layers also is disclosed. Generally, the method involves synthesizing repeating superlattice component layers, thereby forming a superlattice. Novel materials can be made by the particular working embodiments described herein or by using known or hereafter developed synthetic methods. Described working embodiments of the method included preparing superlattice layers by modulated elemental reactants (MER). Superlattices are assembled according to this method by depositing stoichiometrically correct amounts of elements necessary to form the desired stacked component compounds. After the appropriate stoichiometric amounts of materials are deposited, the thin film precursors are annealed to form the desired superlattice component layers. Alternatively, the desired compounds, such as Bi₂Te₃ and TiTe₂, can be directly deposited on a substrate as thin film precursors. Subsequent layers then can be deposited on the first, such that a repeating superlattice structure is formed.

Typically MER yields flakes or chips of superlattice materials. Accordingly, one aspect of the method uses hot isostatic pressing to prepare ingots of bulk superlattices, which are more useful for large scale devices.

### BRIEF DESCRIPTION OF THE DRAWINGS

FIG. 1 is a schematic drawing depicting the Seebeck effect.

FIG. 2 is a schematic drawing depicting the Peltier effect.

FIG. 3 shows X-ray diffraction patterns as a function of annealing temperature for a forming [(Bi₂Te₃)₃(TiTe₂)₃] superlattice.

FIG. 4 is a low angle XRR pattern of a typical Bi—Te precursor film.

FIG. 5 is a low angle XRR pattern of a representative superlattice comprising Bi₂Te₃/TiTe₂.

FIG. 6 is a representative low angle XRR pattern for Bi₂Te₃/TiTe₂ superlattice precursors.

FIG. 7 is an XRD pattern obtained for the Bi₂Te₃/TiTe₂ superlattice system, with each numbered peak indicating a Bragg reflection.

FIG. 8 is a plot of actual repeat layer thickness vs. intended bismuth thickness, where the y-axis intercept is actual thickness of selenium.

FIG. 9A illustrates a calibration method for MER deposition.

FIG. 9B illustrates additional steps of the calibration method of FIG. 9A.

FIG. 10 is a graph of actual repeat layer thickness (Å) vs. intended thickness (Å) for calibrating the deposition of TiTe₂.

FIG. 11 is a plot of the atomic percent of bismuth versus actual thickness of bismuth.

FIG. 12 is a low angle XRD pattern (Log CPS vs. 2θ) for a Bi₂Te₃/HfTe₂ superlattice.

FIG. 13 shows overlaid X-ray diffraction patterns of five isomeric superlattices having the formula [(Bi₂Te₃)ₓ(TiTe₂)_{y}].

FIG. 14 is a graph of thermal conductivity (measured perpendicular to superlattice orientation) versus temperature for a bulk pellet of superlattice material having the formula [(Bi₂Te₃)₆(TiTe₂)₂].

FIG. 15 is a graph of thermal conductivity (measured parallel to superlattice orientation) versus temperature for a bulk pellet of superlattice material having the formula [(Bi₂Te₃)₆(TiTe₂)₂].

FIG. 16 is a graph comparing the lattice thermal conductivity (κ_{L}) of bulk Bi₂Te₃, and two bulk superlattice materials having the formula [(Bi₂Te₃)₆(TiTe₂)₂].

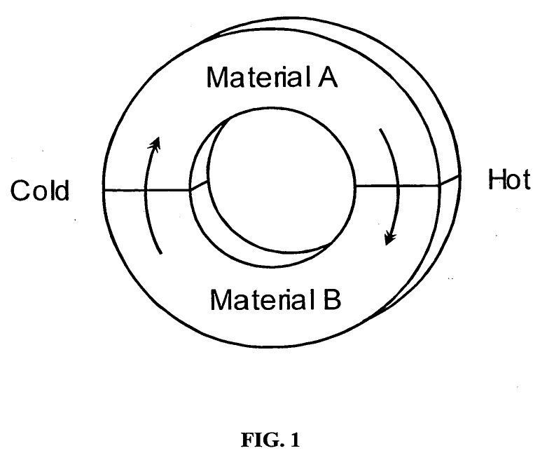

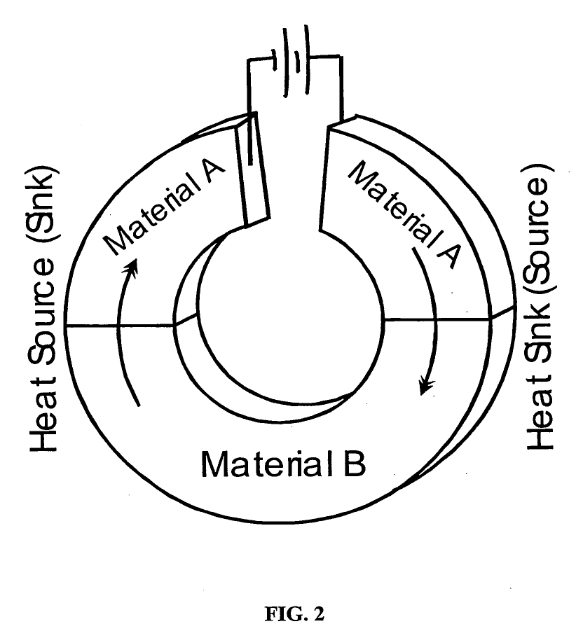

### DETAILED DESCRIPTION

Superlattices are difficult to make by traditional methods. Traditional synthetic techniques do not provide the necessary order to make superlattices. The inability to control the local composition, diffusion, and crystallization has led to the development of new synthetic techniques. Some of the techniques that have been used to create these highly ordered products include pulsed-laser deposition (PLD) and molecular beam epitaxy (MBE), and epitaxial metallorganic chemical vapor deposition (MOCVD). These methods have a significant drawback in that only a small amount of material can be made using these methods. This places a significant restriction on synthesizing bulk amounts for experimental determination and device manufacture.

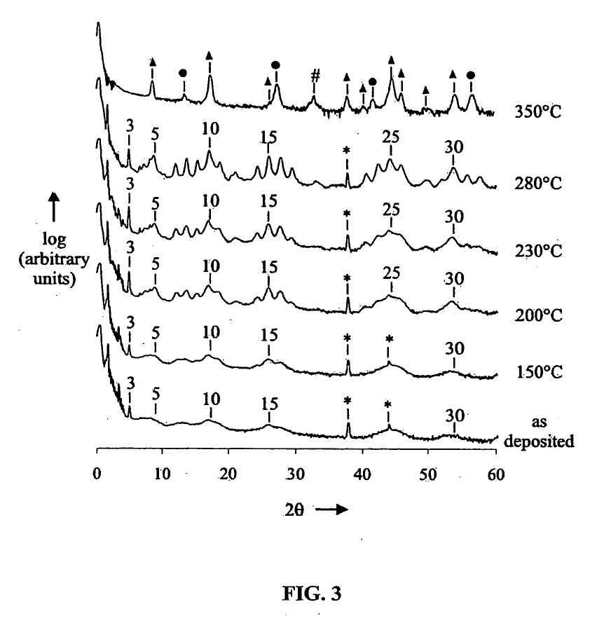

One embodiment of the present method for superlattice synthesis is known as Modulated Material Reactants or Modulated Elemental Reactants (MER), which involves evaporating elements or compounds in a vacuum deposition chamber. According to the technique, stoichiometrically accurate amounts of the desired elements or compounds are deposited, followed by an annealing step to form the desired material. The annealing conditions may be calibrated by monitoring with XRD for Bragg reflections. See, for example, FIG. 3, which provides the results of an annealing study for a Bi₂Te₃/TiTe₂ superlattice. The material evaporation is performed with the vacuum deposition chamber at low pressure, typically less than about 10⁻⁴ torr. More typically, material evaporation is performed at even lower pressures. Working examples used ultra-high vacuum, which is typically less than about 10⁻⁶ torr. However the evaporation may be performed under any conditions sufficient to vaporize a particular material. The evaporation method is specific to the material. In the case of high temperature evaporation, electron beam guns may be used to heat the metal. With lower temperature evaporation, effusion and/or Knudsen cells may be used to heat the source metal to its evaporation temperature under UHV.

According to disclosed embodiments of the synthetic method, desired materials are deposited on a substrate using, for example MER. The substrate material may be selected from the group consisting of silicon, silicon nitride, glass, plastics, insulating oxides, semiconductor materials, quartz, mica, metals, and combinations thereof. Working embodiments used a substrate comprising a silicon wafer.

Such wafers can include other materials deposited thereon. These additional materials can be used, for example, to provide electrical connection between a thermoelectric superlattice and other device components. Working embodiments used wafers spin-coated with a thin layer of polymethylmethacrylate (PMMA). Other suitable insulating or resist materials that can be used in place of, or in combination with PMMA, are other polymeric materials, such as vinyl-derived or polyether materials, such as polystyrene and polyethylene oxide polymers. In working embodiments, the wafer materials were simply used as a substrate for synthesizing materials, which were removed from the substrate after synthesis. Accordingly, after a deposition, the superlattice material can be removed from the substrate by dissolving the PMMA in acetone. The metal sample is then collected by vacuum filtration, and characterized by X-ray reflection (XRR)/diffraction (XRD) studies.

The MER apparatus uses pneumatically activated shutters to select the deposition source. The shutters block the path of material flux, while quartz crystal monitors are used to monitor and control the deposition rate of the sources. Control of the flux allows precise control of the thickness of the precursor elements deposited, which leads to a stoichiometrically correct compound.

Using the MER technique described above, kinetically stable and highly ordered systems, such as superlattices, can be made from thin-film precursors. The samples can then be characterized by differential scanning calorimetry (DSC) to determine the crystallization temperature, as well as the relative nucleation energy as a function of composition. They also can be examined with XRR and XRD to analyze the thickness of deposited layers, as well as the crystalline lattice spacings that form after crystallization. The composition of the samples typically is monitored with Electron Probe Micro Analysis (EPMA).

Thermoelectric superlattices can be prepared according to embodiments of the present method from materials that have good electrical conductivity and low thermal conductivity. Semiconducting materials, such as small bandgap semiconductors, satisfy both requirements.

One effect that has been observed in superlattices is decreased thermal conductivity in both parallel and perpendicular directions. Chen, et al. reported reduced measured thermal conductivity both in-plane and cross-plane in Si/Ge superlattices. Borca-Tasciuc, T.; Song, D.; Liu, J. L.; Chen, G.; Wang, K. L.; Sun, X.; Dresselhaus, M. S.; Radetic, T.; Gronsky, R. In Materials Research Society Symposium Proceedings, 1999; Vol. 545, pp. 473-478. Wu, et al. also observed reduced thermal conductivity in the parallel and perpendicular directions in GaAs/AlGaAs superlattices. Both electronic and lattice effects contribute to the thermal conductivity term κ in Formula 2. The Wiedemann-Franz law states that the electronic contribution to the thermal conductivity is proportional to the electrical conductivity at a given temperature. See, CRC Handbook of Thermoelectrics; Rowe, D. M., Ed.; CRC Press: New York, 1995. To change the electronic contribution, it would be necessary to change the electrical conductivity. The lattice contribution to thermal conductivity is associated with phonons traveling through the lattice, and adjustments to this physical property may yield the best opportunity to minimize thermal conductivity without affecting a material's electrical properties.

Two main approaches have been used to reduce the lattice thermal conductivity. The first approach involves using rattling atoms to refract phonons. Rattling atoms are heavy atoms loosely bound in voids within a crystalline lattice. Rattling atoms move more freely than the strongly bound atoms of the crystalline lattice, and thus can refract phonons traveling through the material. Common rattling-atom-based materials are skutterudites and clathrates.

The second approach to reduce lattice thermal conductivity involves using superlattices, which is the approach adopted herein. In superlattice structures, several mechanisms responsible for minimizing thermal transport are theorized. The first mechanism by which thermal transport is minimized involves lowering the minimum phonon energies required to produce Umklapp scattering processes relative to that of an alloy including the component superlattice materials. Other factors are phonon wave reflection at superlattice interfaces when the phonon wavelength fulfills the Bragg condition, or when an acoustic mismatch is encountered. Venkatasubramanian, R.; Colpitts, R. In Thermoelectric Materials—New Directions and Approaches; Tritt, T. M.; Kanatzidis, M. G.; Hylan B.; Lyon, J.; Mahan, G. D., Eds.; Materials Research Society: San Francisco, Calif., 1997; Vol. 478, pp. 73-84; Venkatasubramanian, R.; Slivola, E.; Colpitts, T.; O'Quinn, B. Nature, 2001, 413, 597-602.

Superlattices are defined as having repeating structure, where the repeating layers are crystallographically oriented as detected by superlattice Bragg reflections, and which have at least four component layers. Thus, superlattices comprise a repeat unit having at least two component layers, with the repeating unit repeating at least once. The different materials in the repeat unit scatter phonons. Since the electrical conductivity and Seebeck coefficient are not independent, it is very difficult to change these terms experimentally to increase efficiency. However, the lattice thermal conductivity is one variable that can be adjusted to optimize Z.

If the transition between the two materials is abrupt, thermal conductivity is reduced. To ensure that the transition is abrupt, typically each material extends for whole numbers of unit cells. The presence of abrupt transitions can be readily confirmed by observation of characteristic Bragg reflections in the X-ray diffraction pattern. The MER method discussed above provided the precision necessary to deposit the correct stoichiometric amounts of materials to correspond to integer numbers of unit cells. Thus, in working examples, one or more unit cells of a first material were prepared on one or more unit cells of a second material, thereby forming a new, superlattice repeat unit including both materials. The superlattice repeat unit was then repeated or stacked one or more times to form the superlattice.

Good thermoelectric materials ideally have a high power factor value. High power factor typically refers to a power factor of at least about 0.1 Wm⁻¹K⁻¹. High power factors that have been observed typically range from 0.1 to 5 Wm⁻¹K⁻¹; however, materials having higher power factors should be able to exist. Examples of materials having high power factors include, without limitation, Bi₂Te₃, Sb₂Te₃, CoSb₃, HfNiSn and PbTe.

Component layers of the superlattice may be any thickness that yields good thermoelectric properties for the bulk superlattice. Typically the minimum thickness is about the thickness of a unit cell for the particular material, and the maximum thickness is such that the material retains useful thermoelectric properties. Useful thermoelectric materials typically have a high figure of merit. With reference to Formula 2, a high figure of merit typically yields a ZT value of at least about 0.5 at the temperature of desired use. Typically each component layer has a thickness of from about 3 Å, to several hundred angstroms. Typically a superlattice repeat unit, made from the component layers, can have a lower thickness limit of about 6 Å, and a large upper thickness limit, such as at least about 500 Å, more typically between about 50 Å and about 100 Å, with working embodiments having superlattice repeat unit thicknesses of from about 40 Å to about 50 Å. The upper thickness limit is material-dependent.

According to the MER technique, superlattices are prepared using thin film, multilayer precursors. The thin film precursors are provided as the individual, various elements needed for a final product, and are deposited sequentially on a substrate. Various elements can be deposited using MER, including elements that may be defined as metals, rare earth metals or metalloids. Typical examples of elements useful for forming superlattices deposited by MER include antimony, bismuth, hafnium, lead, selenium, tellurium. titanium, zirconium and combinations thereof.

Embodiments of the presently disclosed superlattices typically include at least a first layer comprising BiₓSb₂₋ₓSe_{y}Te_{3-y}, or PbSe_{z}Te_{1-z}, where 0≦x≦2, 0≦y≦3, and 0≦z≦1. Typically the first layer includes a material having a high power factor.

The disclosed superlattices also usually include a second layer, which functions as a diffusion barrier. Such diffusion barriers are designed to include materials that have slower interdiffusion rates. Embodiments of diffusion barriers for use in the present superlattices include compounds such as selenides and tellurides. Typical embodiments include compounds having a general formula ASe_{z}Te_{2-z}, where A can be Ti, Zr, Hf. V, Nb, Ta, Cr, Mo, W., and combinations thereof, and 0≦z≦2. Without limitation to theory, it currently is believed that materials preferred for use as diffusion barriers have strong atomic bonds, and are substantially immiscible in and have a similar crystal structure to, the other superlattice component(s) materials. For example, TiTe₂ has strong atomic bonds, is immiscible in, and has a similar crystal structure to an exemplary superlattice material used for the first layer, Bi₂Te₃. Thus, certain working embodiments have used TiTe₂ as a diffusion barrier. A second diffusion barrier used in working embodiments with Bi₂Te₃ is HfTe₂, which corresponds to the formula ASe_{z}Te₂₋ₓ, where z is 0 and A is hafnium.

Certain embodiments include a third layer comprising a different material than in the first layer, but also having the formula BiₓSb₂₋ₓSe_{y}Te_{3-y}, or PbSe_{z}Te_{1-z}, where 0≦x≦2, 0≦y≦3, and 0≦z≦1. Typical embodiments have a layer including a material where y=0, to provide BiₓSb₂₋ₓTe_{3-y} where 0≦x≦2. Working embodiments used superlattice layers including Bi₂Te₃, which corresponds to the formula BiₓSb₂₋ₓSe_{y}Te_{3-y} where x is 2 and y is zero.

Without limitation to theory, phonon scattering is thought to be more prevalent in superlattices that have sharp interfaces between crystalline structures. Thus, superlattices having such sharp interfaces should exhibit reduced thermal conductivity. To ensure an abrupt electronic density change between superlattice layers, the layers should remain substantially distinct. The diffusion barrier is included in disclosed superlattices to ensure that interdiffusion of superlattice materials is minimized. To produce superlattices having the desired, substantially distinct layers, a diffusion barrier can be included between each adjacent layer, only between certain layers, or perhaps between only one pair of layers. The diffusion layer may be deposited by any suitable technique. For example, a diffusion layer can be deposited by MER.

Until now, Bi₂Te3/Sb₂Te₃ superlattices have been synthesized only as thin films. The calculation of ZT for thin films is not straightforward. The method for measuring the thermal conductivity of thin films is known as the 3ω technique. The details of this technique are explained elsewhere. Borca-Tasciuc, T.; Song, D.; Liu, J. L.; Chen, G.; Wang, K. L.; Sun, X.; Dresselhaus, M. S.; Radetic, T.; Gronsky, R. In Materials Research Society Symposium Proceedings, 1999; Vol. 545, pp. 473-478; Cahill, D. Rev. Sci. Instrum. 1990, 61, 802-808. Because superlattices are intended for bulk use to make high Z thermoelectric materials, there is cause for concern that the thermal conductivity measurements obtained from thin films will not accurately depict the thermal conductivity for the equivalent bulk superlattice structures. In bulk, other factors, such as grain boundaries and orientation of the various particles in a three-dimensional space, can affect the thermoelectric properties. In previous reports of thin film Bi₂Te₃/Sb₂Te₃ superlattices, calculations imply that the superlattices could offer a three to four-fold decrease in the thermal conductivity over bulk Bi_{0.4}Sb_{1.6}Te₃ alloys. Venkatasubramanian, R.; Colpitts, T. In Thermoelectric Materials—New Directions and Approaches; Tritt, T. M., Kanatzidis, M. G., Hylan B. Lyon, J., Mahan, G. D., Eds.; Materials Research Society: San Francisco, Calif., 1997; Vol. 478, pp. 73-84. This claim remains to be tested on bulk superlattice samples.

Bulk amounts of superlattices with varying superlattice repeat distances have been prepared, verifying that the MER method can be used to synthesize these superlattices with sharp interfaces. The properties of the material are then tested to determine the ZT of the material in the bulk. An optimal superlattice thickness for the bulk material can be determined that achieves a preferred or maximum figure of merit, ZT.

MER evaporation techniques have been developed to deposit elemental layers on a substrate. Because thin elemental layers can be deposited by the method, interdiffusion and crystallization can occur at very low temperatures. Thus, since the elements do not have to travel very far to find their respective elemental matches, the superlattices might be grown easily. Noh, M. In The synthesis and characterization of crystalline superlattices ((TiSe₂)(ₗ)(NbSe₍₂₎)₍ₘ₎)₍ₙ₎: A new thin-film growth technique using multilayer reactants. Ph.D. Thesis, Chemistry; University of Oregon: Eugene, Oreg., 1997, UMI No. 9818734.

A compound or compounds having a crystal structure similar to Bi₂Te₃ and Sb₂Te₃ were deemed preferable for the interdiffusion barrier. It is also thought that diffusion barrier materials having strong interatomic bonds are more effective due to slower diffusion rates. Thus, TiTe₂ and HfTe₂ were selected for use as diffusion barrier materials for certain working embodiments, because (1) these compounds have a layered crystal structure comprising hexagonal sheets, much like bismuth telluride and antimony telluride, (2) titanium-tellurium and hafnium-tellurium bonds are strong, and (3) the compounds are insoluble in bismuth telluride. Oftedal, I. Z. physik. Chem. 1928, 134, 301-310. All three of these features are believed to minimize interdiffusion the diffusion barrier with the material having a high power factor, which preserves the sharp interfaces between the different materials. Thus, by minimizing interdiffusion, the diffusion barrier reduces thermal conductivity.

Binary (two different materials) superlattices, including Bi₂Te₃ and TiTe₂ and superlattices comprising Bi₂Te₃ and HfTe₂ component layers, were prepared. The synthesis of the Bi₂Te₃/TiTe₂ superlattices illustrates the use of diffusion barriers to synthesize superlattices by the MER technique.

To synthesize the Bi₂Te₃/TiTe₂ superlattice the deposition of elemental Bi and Te layers was first calibrated. Since the target compound was Bi₂Te₃, the relative thicknesses between the Bi and Te were correlated to provide the desired stoichiometry. For this application, Bi thicknesses ranging from about 24 Å to about 33 Å corresponded to an atomic % of from about 30% to about 40%. Similarly, Te thickness of about 51 Å provided, with varying amounts of Bi, from about 60 to about 70 atomic % Te. During this calibration, a series of Bi—Te samples were deposited. The Te thicknesses were held constant while the Bi thicknesses were varied. Table 1 lists the samples that were used to calibrate the Bi—Te system's stoichiometry. The composition data in Table 1 was determined from EPMA performed on floated flakes of material, which determines the ratio of Bi and Te atoms independent of structure.

TABLE 1
Calibration of Bi—Te deposition.

| Intended | Intended | | |
|---|---|---|---|
| Thickness Bi | Thickness Te | | |
| (Å) | (Å) | Atomic % Bi | Atomic % Te |
| 24 | 51 | 31.7 | 68.3 |
| 27 | 51 | 37.6 | 62.4 |
| 30 | 51 | 38.1 | 61.9 |
| 33 | 51 | 39.7 | 60.3 |

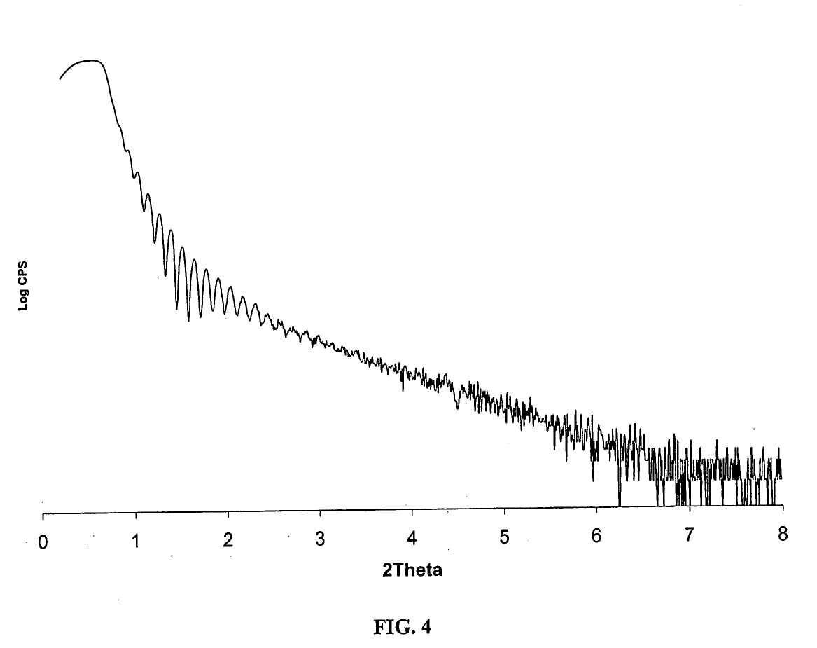

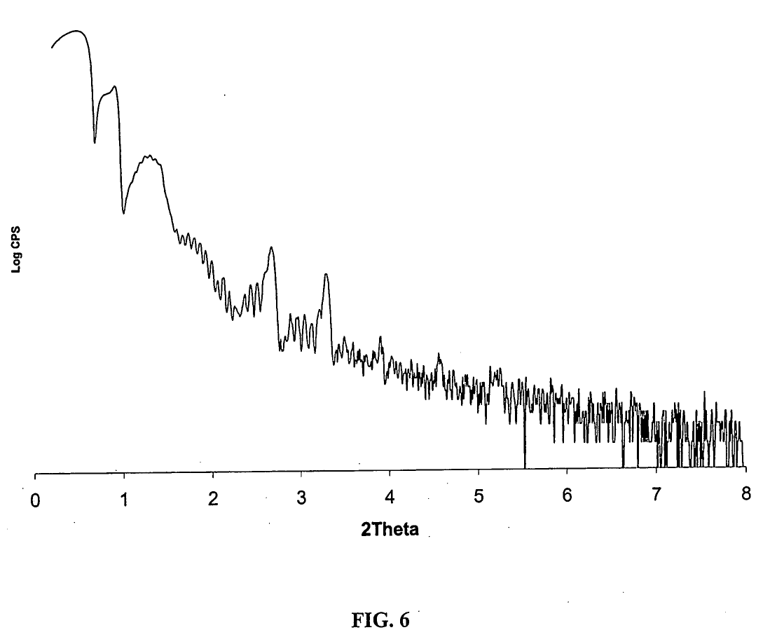

Layer thickness also was optimized during the system calibration so that each layer ended on a unit cell, thus providing a van der Waals gap (VWG). Low angle, X-ray reflectivity experiments can be used to evaluate layer thickness. However, with reference to FIG. 4, which shows a typical low angle reflectivity pattern for the Bi-Te system, the only peaks that appear in the low angle are front surface to back surface reflections. In an ideal reflection pattern of a multi-element layered film, a Bragg peak appears at a higher 2 theta value that corroborates the total thickness data (see FIG. 6). Much like the Bi₂Te₃ system, the TiTe₂ system was calibrated for stoichiometry and thickness.

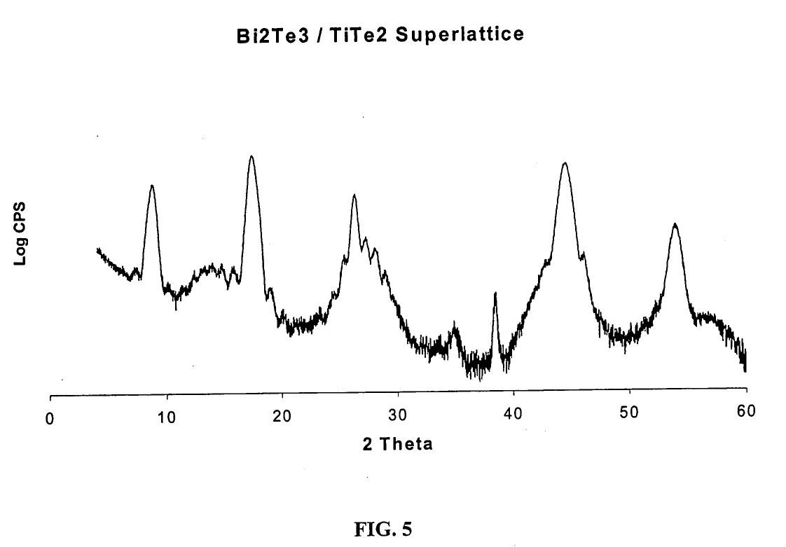

FIG. 5 illustrates a representative superlattice from an initial preparation of Bi₂Te_{3/}TiTe₂. Preliminary calibrations from the two binary systems were sufficient to enable formation of a superlattice, which is evidenced by the higher order Bragg components observed in the spectrum of FIG. 5.

The crystal structures of Bi₂Te₃ and TiTe₂ are similar in that they are both layered hexagonal systems that contain VWGs in between the repeating units. When synthesizing superlattices with crystal structures such as these, each material preferably ends on its VWG. With this strategy the correct stoichiometry, and also the correct amount of each material, preferably is deposited. The superlattice spacing between repeating units can be calculated using Bragg's law and, for example, the peaks from FIG. 5. In a superlattice having regular repeats, all of the peaks represent the same thickness.

FIG. 6 shows a representative low angle reflection pattern for an as-deposited Bi₂Te₃/TiTe₂ superlattice precursor sample. Bragg peaks can be seen describing the repeat layer thickness. Since these Bragg peaks only describe the total repeat of the Bi—Te layers as well as the Ti—Te layers, the individual thickness of the Bi—Te regions as well as the Ti—Te regions cannot be determined from one sample.

However, a technique was developed to determine the thicknesses of all of the regions. In this technique, a series of superlattice precursors were deposited in which one superlattice component was varied while the other was held constant. For example, a working embodiment held the Bi—Te layers constant and varied the Ti—Te layers. By using the low angle X-ray reflection data, the various superlattice repeat distances can be plotted as a function of intended Ti—Te thickness. The slope of the resulting line provides the thickness of the Ti—Te layers, and the y-intercept provides the Bi—Te thickness. Once the thickness values have been obtained for the different layers, corrections in the monitored thickness can be made for the next deposition set. The process can then be repeated with the calibrated values.

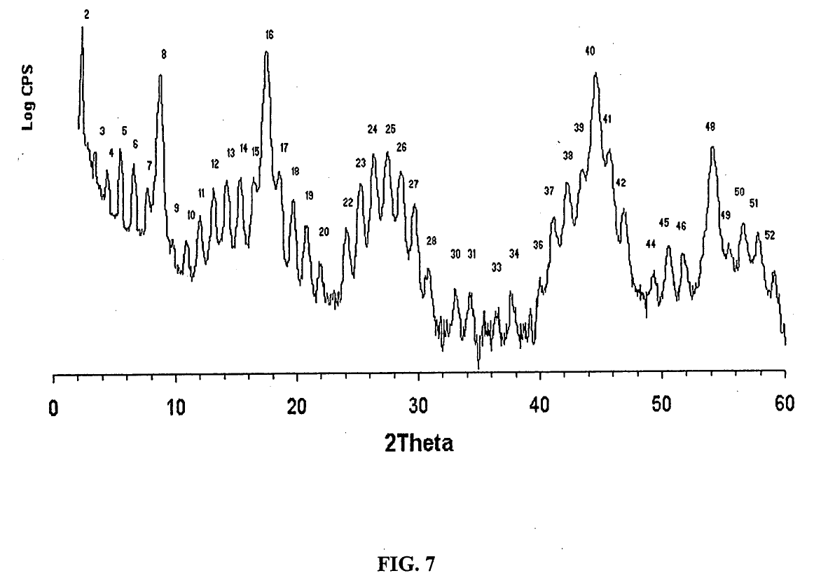

Once the optimal thicknesses have been achieved, the result is an ideal Bi₂Te₃/TiTe₂ superlattice. FIG. 7 shows the high angle diffraction pattern of the Bi₂Te₃/TiTe₂ superlattice having both optimal stoichiometry and thickness. The superlattice repeat distance can be calculated from the diffraction peaks in FIG. 7. Once the thicknesses are calibrated, the uncertainty of the calculated superlattice thickness becomes very narrow so that superlattices having precise stochiometries can be prepared.

### EXAMPLES

The following examples are provided to illustrate certain particular embodiments of the disclosure. It should be understood that additional embodiments not limited to these particular features described are consistent with the following examples.

### Example 1

Using commercially available effusion cells (available from Applied Epi, http://www.appliedepi.com/), bulk superlattices containing Bi₂Te₃/TiTe₂ layers were prepared by sequentially depositing layers of bismuth and tellurium, followed by titanium and tellurium layers. The layers were deposited so as to provide the correct stoichiometric composition and absolute amount of each element to prepare the targeted number of Bi₂Te₃ and TiTe₂ layers, each layer being a unit cell. The deposition can be controlled to produce any ratio of Bi₂Te₃ and TiTe₂ layers. Using this method superlattices having the repeating units [(Bi₂Te₃)₂(TiTe₂)₂], [(Bi₂Te₃)₃(TiTe₂)₃], [(Bi₂Te₃)₄(TiTe₂)₄], [(Bi₂Te₃)₅(TiTe₂)₅] and [(Bi₂Te₃)₆(TiTe₂)₆], [(Bi₂Te₃)₆(TiTe₂)₂] were prepared. The deposited precursor was then annealed to kinetically trap the desired superlattice product. Superlattices and superlattice precursors prepared according to the present method were characterized by X-ray diffraction. XRR is useful in describing the deposited layers after a deposition.

Another useful technique is EPMA, which is useful for determining the elemental composition of materials prepared using the modulated elemental reactant technique. The precision of this instrument is usually within 1-2 atomic percent.

### Example 2

This example describes the calibration process for deposition of superlattice precursors. Calibrations are performed by making binary samples with repeating layers of two elements. One element thickness must be kept constant, while the other thickness is varied. The samples are then analyzed by XRD and EPMA.

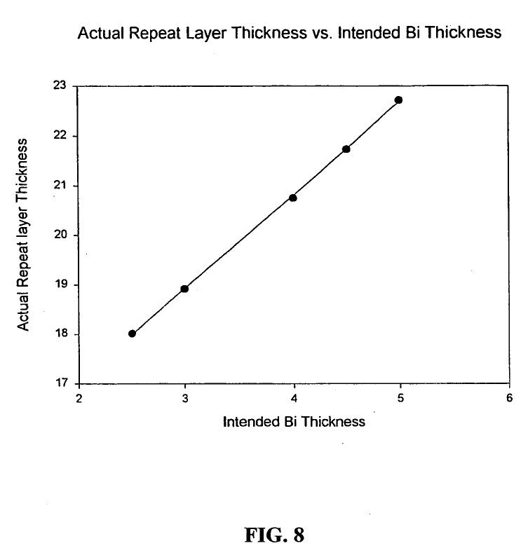

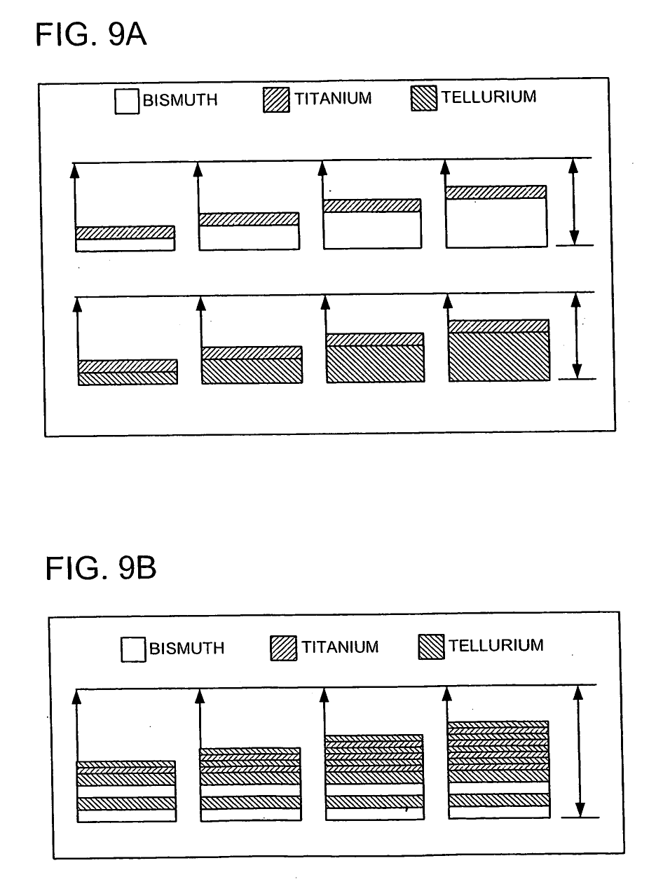

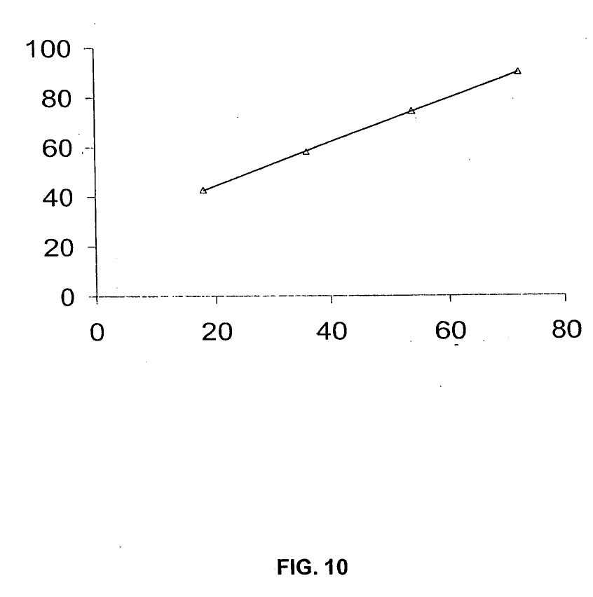

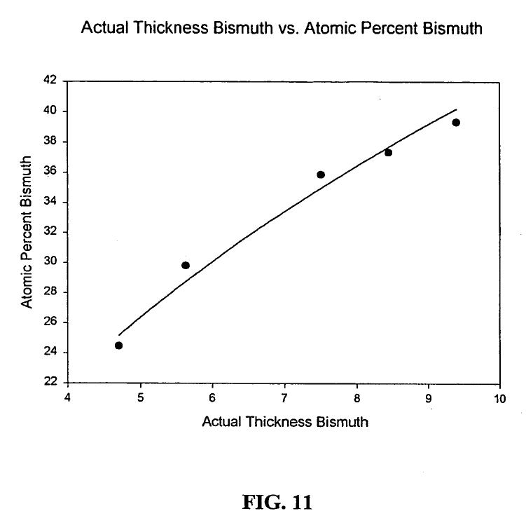

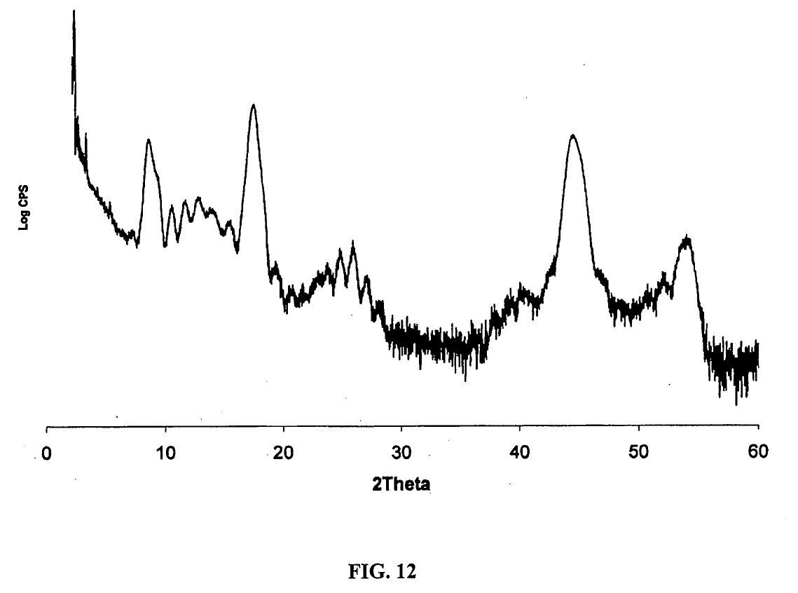

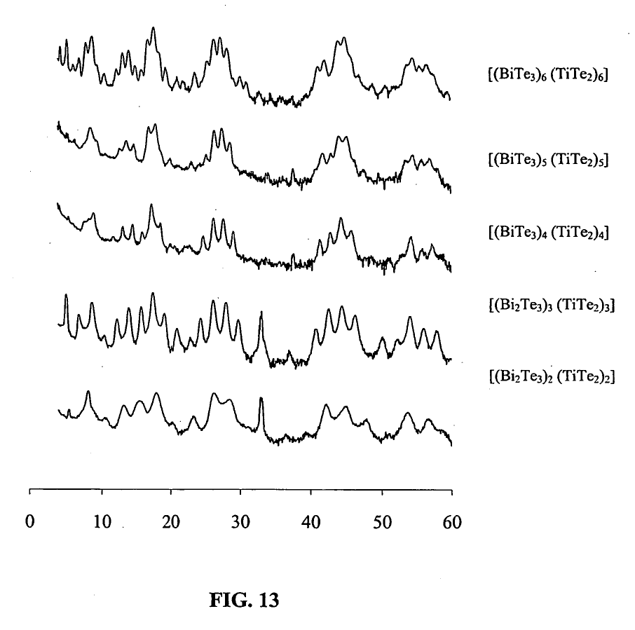

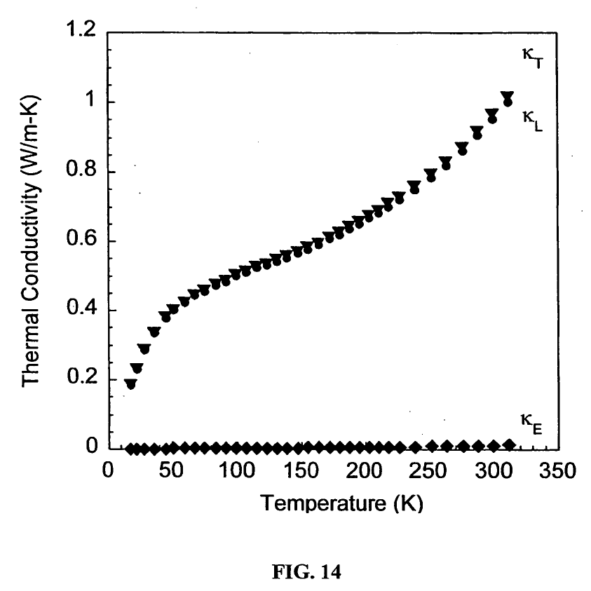

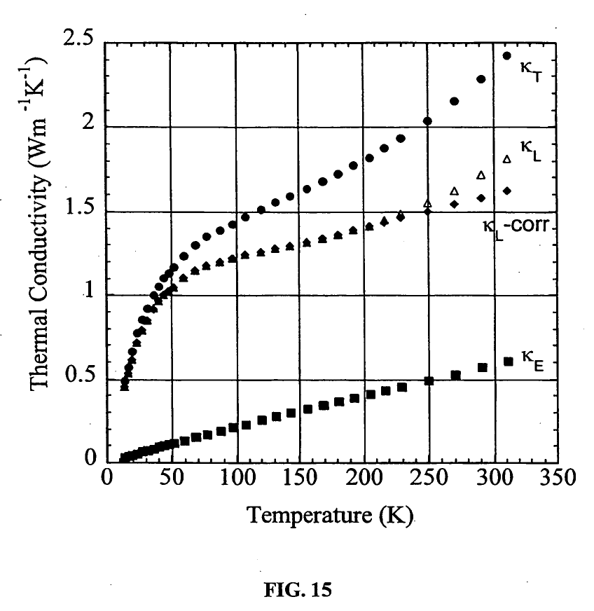

FIGS. 9A, 9B and 10 illustrate the calibration process for MER deposition. With reference to FIGS. 9A and 9B, samples were made by systematically changing the layer thickness of bismuth while holding the layer thickness of tellurium constant. Composition was determined by EPMA, and the ratio of layer thicknesses resulting in Bi₂Te₃ stoichiometry was selected for synthesis of the subsequent superlattice precursors. Similarly, titanium-tellurium binaries were synthesized and analyzed by EPMA to determine the thicknesses resulting in a TiTe₂ stoichiometry. With continued reference to FIGS. 9A and 9B, once the thickness ratios in the binaries were determined, a series of samples with an approximate 1000 Å thickness was made by combining both binary systems into alternating layers. A systematic series of these samples was made that changed the TiTe₂ thickness and left the Bi₂Te₃ thickness constant. Each sample of the series were made with an approximate 1000 Å. The actual repeat layer thickness of the system (determined from XRR) can be plotted against the intended thickness of the varied component (TiTe₂) of the deposited material to give a thickness calibration of the system. This process was repeated until the desired thicknesses were obtained. These plots can be seen in FIGS. 8, 10 and 11. Absolute amounts of each binary multilayer were adjusted by analyzing this graph and preparing additional samples in the series of systematically varied superlattice precursors to determine the thickness of each component layer.

### Example 3

This example describes an annealing study to determine the optimal annealing conditions for forming Bi₂Te₃/TiTe₂ superlattices. XRD can be used to monitor crystallization as a function of annealing temperature. XRD is characterized by the diffraction of X-rays that occurs within the lattice planes of a crystalline structure.

A [(Bi₂Te₃)₃(TiTe₂)₃] superlattice precursor was deposited using MER and analyzed using XRD. The sample was then monitored via XRD as the sample was annealed. A summary of the XRD results is recorded in FIG. 3. The XRD study indicates that structural order perpendicular to the substrate increases as a function of annealing temperature. Specifically, the Bi₂Te₃ layers, each of which had a thickness of 10.0 A, yielded diffraction maxima at 2θ values of 8.8°, 17.6°, 26.4° and 44.0°, while the TiTe₂ layers, each of which had a thickness of 6.5 Å, yielded diffraction maxima at 2θ values of 13.6°, 27.2°, 40.8°and 54.4°. With continued reference to FIG. 3, weak diffraction maxima are observed at 40.8° and 54.4° in the initially deposited superlattice precursor, which indicates the presence of small crystallites of Bi₂Te₃ and TiTe₂, respectively. As the sample is annealed, the characteristic peaks corresponding to the superlattice increase in intensity and resolution. However, the superlattice begins to disproportionate into its constituent binary compounds at about 300° C., and diffraction peaks corresponding to the phase separated compounds are observed in the 350° C. spectrum. The diffraction data resulting from the modulated nature of the precursors tracks the evolution of the sample with temperature and time permitting the annealing conditions to be efficiently optimized.

Rocking curve scans also were collected as a function of annealing temperature to monitor the evolution of interfacial roughness in the multilayer [from the (0 0 1) reflection] and the changes in the alignment of the crystallites that form from the (0 0 8) and (0 0 10) reflections (these areas in the XRD pattern depend on the layer spacing of TiTe₂ and Bi₂Te₃, respectively). The (0 0 1) rocking curve scan indicates little change in the diffuse scattering up to 240° C. Above 240° C., the diffuse scattering becomes more intense, indicating that the interfacial roughness of the multilayer is increasing. The full width at half maximum (FWHM) of both the (0 0 8) and (0 0 1 0) high angle rocking curves narrow steadily from 8 and 10 degrees, respectively, at 160° C. to 3.2 degrees at 280° C.

### Example 4

This example describes the preparation of pellets of bulk superlattices having the repeating unit [(Bi₂Te₃)₆(TiTe₂)₂]. Flakes of bulk [(Bi₂Te₃)₆(TiTe₂)₂] were prepared via MER deposition, followed by annealing at approximately 270° C. The annealing process was monitored by XRD for the presence of the characteristic Bragg reflections corresponding to superlattice formation. After annealing several flakes were combined in a mold and subjected to hot isostatic pressing under a vacuum at 300° C. using a pressure of 700 MPa for 10 hours. Two ingots were prepared according to this protocol, with the first (parallel ingot) having dimensions of 2.013 by 8.030 by 2.058 mm, weighing 224.8 mg and having superlattice Van der Waals gaps oriented parallel to the longest dimension of the ingot. The superlattice orientation can be selected by placing the flakes in the mold in the desired orientation. The second (perpendicular) ingot had the dimensions 3.031×3.026×9.32, 9.332, weighed 517.3 mg, and had Van der Waals gaps oriented perpendicularly to the longest dimension of the ingot.

XRD analysis of both pellets after hot pressing confirmed, by the presence of characteristic Bragg reflections, that the superlattice structure was retained. The thickness of each superlattice layer [(Bi₂Te₃)₆(TiTe₂)₂] was 76 Å, as calculated from Bragg's formula.

The two ingots were fully characterized with respect to their thermoelectric properties. Several properties can be further optimized. For example, the perpendicular ingot had a Seebeck coefficient of about ×47 μV/K and a resistivity of about 62 mΩ•cm at 300 K, whereas the parallel ingot had a Seebeck coefficient of about ×47 μV/K and a resistivity of about 1.2 mΩ•cm at 300 K. The resistivity of the parallel sample is comparable to that of Bi₂Te₃. However, the resistivity of the perpendicular sample is significantly higher. The Seebeck coefficients for both samples are about five-fold lower than that of Bi₂Te₃. However, both the resistivity and the Seebeck coefficient can be tuned by, for example optimizing the number of carriers. The number of carriers can be increased or decreased by doping with an appropriate material. For example, the Seebeck coefficient can be increased by decreasing the number of carriers. One known method for doping the present materials includes substituting a fraction of one chalcogen for another. For example, a percentage of the tellurium present in Bi₂Te₃ can be replaced with selenium.

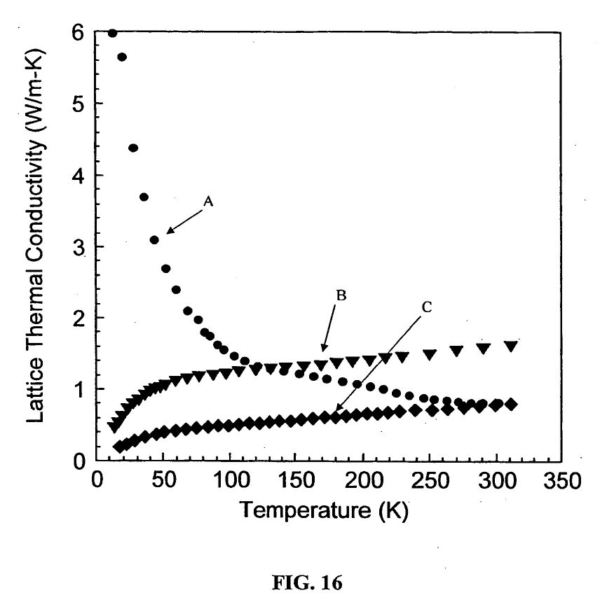

Both superlattice samples exhibited reduced thermal conductivity as compared to the bulk materials. FIG. 16 compares the lattice thermal conductivity (κ_{L}) of the novel bulk superlattice materials, prepared as above, with bulk Bi₂Te₃ (sample C), which is a currently commercially successful thermoelectric material. The κ_{L} was measured lengthwise on each sample. As a result, κ_{L} was measured parallel (sample A) and perpendicular (sample B) to the superlattice orientation. The superlattice materials exhibit significantly lower κ_{L} than Bi₂Te₃ at low temperature, and comparable κ_{L} at higher temperatures, such as room temperature.

The present invention has been described with reference to preferred embodiments. Other embodiments of the invention will be apparent to those of ordinary skill in the art from a consideration of this specification, or practice of the invention disclosed herein. It is intended that the specification and examples be considered as exemplary only, with the true scope and spirit of the invention being indicated by the following claims.

We claim:

1. A composition, comprising:
a first layer comprising a material having a high power factor; and
a second layer comprising a diffusion barrier.

2. The composition according to claim I where the material having a high power factor has a formula BiₓSb₂₋ₓSe_{y}Te_{3-y}, or PbSe_{z}Te_{1-z} where 0≦x≦2, 0≦y≦3, and 0≦z≦1.

3. The composition according to claim 1 where the diffusion barrier comprises a material having a formula ASe_{z}Te_{2-z}, where A is selected from the group consisting of Ti, Zr, Hf, V, Nb, Ta, Cr, Mo, W, and combinations thereof, and 0≦z≦2.

4. The composition according to claim 1 where the first layer comprises at least one of Bi₂Te₃, Sb₂Te₃, Bi₂Se₃, Sb₂Se₃, TiTe₂, HfTe₂, ZrTe₂, PbTe, TiSe₂, HfSe₂, ZrSe₂, PbSe, alloys thereof, and combinations thereof.

5. The composition according to claim 1 where the first layer and the second layer are repeating layers forming a superlattice.

6. The composition according to claim 1 where the first layer and the second layer form a repeating unit.

7. The composition according to claim 5 where the first repeating layer comprises Bi₂Te_{3.}

8. The composition according to claim 1 where the first layer includes Bi₂Te₃, and the second layer includes TiTe_{2.}

9. The composition according to claim 5 where the first repeating layer comprises Sb₂Te_{3.}

10. The composition according to claim 5 where the second repeating layer comprises HfTe₂, TiTe₂, or both.

11. The composition according to claim 5 further comprising a third repeating layer.

12. The composition according to claim 11 where the third repeating layer comprises a material having a formula Bi,Sb₂₋ₓSe_{y}Te_{3-y}, or PbSe₂Te_{1-z}, where 0≦x≦2,0≦y≦3, and 0≦z≦1.

13. The composition according to claim 11 further comprising a fourth repeating layer.

14. The composition according to claim 13 where the fourth repeating layer comprises a diffusion barrier material.

15. The composition according to claim 13 where the fourth repeating layer comprises a material having a formula ASeTe_{2-z}, where A is selected from the group consisting of Ti, Zr, Hf. V, Nb, Ta, Cr, Mo, W, and combinations thereof, and 0≦z≦2.

16. The composition according to claim 11 where each layer is from about 3 to about 200 Å thick

17. The composition according to claim 13 where the first, second, third and fourth layers comprise a repeating unit.

18. The composition according to claim 13 where the first layer comprises Bi₂Te_{3.}

19. The composition according to claim 13 where the second layer comprises TiTe_{2.}

20. The composition according to claim 6 where the repeating unit is from about 6 to about 500 Å thick.

21. The composition according to claim 6 where the repeating unit is from about 40 to about 100 Å thick.

22. The composition according to claim 11 comprising Bi₂Te₃, TiTe₂, and Sb₂Te_{3.}

23. The superlattice according to claim 13 where the second and fourth layers comprise a material having a formula ASeTe_{2-z}, where A is selected from the group consisting of Ti, Zr, Hf, V, Nb, Ta, Cr, Mo, W, and combinations thereof, and 0≦z≦2.

24. The composition according to claim 23 where each layer of the repeating unit comprises at least one of Bi₂Te₃, TiTe₂, and Sb₂Te_{3.}

25. The composition according to claim 17 comprising a repeating unit having a first layer including Bi₂Te₃, a second layer including TiTe₂, a third layer including Sb₂Te₃, and a fourth layer including TiTe₂.

26. A method for making a thermoelectric superlattice, comprising:
synthesizing a first material, the first material having a formula Bi,Sb₂₋ₓSe_{y}Te_{3-y}, or PbSe_{z}Te_{1-z} where 0≦x≦2, 0≦y≦3, and 0≦z≦1; and
synthesizing a second material on the first material, the second material being a diffusion barrier.

27. The method according to claim 26 where the second material has the formula ASe_{z}Te_{2-z}, where A is selected from the group consisting of Ti, Zr, Hf, V, Nb, Ta, Cr, Mo, W, and combinations thereof, and 0≦z≦2.

28. The method according to claim 26 where the first material is synthesized by MER.

29. The method according to claim 26 further comprising synthesizing a third material, the third material having a formula BiₓSb₂₋ₓSe_{y}Te_{3-y}, or PbSe_{z}Te_{1-z} where 0≦x≦2, 0≦y≦3,and 0≦z≦1.

30. The method according to claim 26 where the second material is synthesized by MER.

31. The method according to claim 29 further comprising synthesizing a fourth material, the fourth material being a diffusion barrier.

32. The method according to claim 26 where the first material and the second material are synthesized as a repeating unit.
